(19) United States
(12) Patent Application Publication
(10) Pub. No.: US 2026/0052719 A1
(43) Pub. Date: Feb. 19, 2026

(54) NITRIDE-BASED SEMICONDUCTOR DEVICE AND METHOD FOR MANUFACTURING THE SAME

(71) Applicant: INNOSCIENCE (SUZHOU) SEMICONDUCTOR CO., LTD., Suzhou, Jiangsu (CN)

(72) Inventors: Peng-Yi WU, Suzhou, Jiangsu (CN); Chuan Gang LI, Suzhou, Jiangsu (CN); Yuanyu WU, Suzhou, Jiangsu (CN)

(73) Assignee: INNOSCIENCE (SUZHOU) SEMICONDUCTOR CO., LTD., Suzhou, Jiangsu (CN)

(21) Appl. No.: 19/103,980

(22) PCT Filed: Aug. 16, 2022
(86) PCT No.: PCT/CN2022/112840

§ 371 Date: Feb. 14, 2025

(51) Int. Cl. H10D 30/47; H10D 30/01; H10D 62/85

(52) U.S. Cl. CPC H10D 30/475; H10D 30/015; H10D 62/8503

(57) ABSTRACT

A semiconductor device includes a first III-V nitride-based layer, a second III-V nitride-based layer, a nitride-based transition layer, and a nitride-based transistor. The first III-V nitride-based layer is disposed over a substrate by applying a first V/III ratio in a first range. The second III-V nitride-based layer is disposed over the first III-V nitride-based layer by applying a second V/III ratio in a second range, in which the first range and the second range are mutually exclusive. The nitride-based transition layer is disposed between the first III-V nitride-based layer and the second III-V nitride-based layer to connect the first III-V nitride-based layer with the second III-V nitride-based layer, in which the nitride-based transition layer is formed by applying a third V/III ratio in a third range between the first range and second range. The nitride-based transistor is disposed over the second III-V nitride-based layer.

### CROSS-REFERENCE TO RELATED APPLICATIONS

This application is a national stage of international PCT Application No. PCT/CN2022/112840 filed on Aug. 16, 2022, the entire contents of which are incorporated herein by reference.

### FIELD OF THE DISCLOSURE

The present disclosure generally relates to a nitride-based semiconductor device. More specifically, the present disclosure relates to a nitride-based semiconductor device having a varied V/III ratio to improve epitaxial growth quality.

### BACKGROUND OF THE DISCLOSURE

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

### SUMMARY OF THE DISCLOSURE

In accordance with one aspect of the present disclosure, a semiconductor device is provided. The semiconductor device includes a first III-V nitride-based layer, a second III-V nitride-based layer, a nitride-based transition layer, and a nitride-based transistor. The first III-V nitride-based layer is disposed over a substrate by applying a first V/III ratio in a first range. The second III-V nitride-based layer is disposed over the first III-V nitride-based layer by applying a second V/III ratio in a second range, in which the first range and the second range are mutually exclusive. The nitride-based transition layer is disposed between the first III-V nitride-based layer and the second III-V nitride-based layer to connect the first III-V nitride-based layer with the second III-V nitride-based layer, in which the nitride-based transition layer is formed by applying a third V/III ratio in a third range between the first range and second range. The nitride-based transistor is disposed over the second III-V nitride-based layer.

In accordance with one aspect of the present disclosure, a method for manufacturing a semiconductor device is provided. The method includes steps as follows. A first III-V nitride-based layer is formed over a substrate by applying a first V/III ratio in a first range. A second III-V nitride-based layer is formed over the first III-V nitride-based layer by applying a second V/III ratio in a second range, in which the first range and the second range are mutually exclusive. A nitride-based transition layer is formed between the first III-V nitride-based layer and the second III-V nitride-based layer to connect the first III-V nitride-based layer with the second III-V nitride-based layer, in which the nitride-based transition layer is formed by applying a third V/III ratio in a third range between the first range and second range. A nitride-based transistor is formed over the second III-V nitride-based layer.

In accordance with one aspect of the present disclosure, a nitride-based semiconductor device is provided. The nitride-based semiconductor device includes a first III-V nitride-based layer, a second III-V nitride-based layer, a nitride-based transition layer, and a nitride-based transistor. The first III-V nitride-based layer is disposed over a substrate. The second III-V nitride-based layer is disposed over the first III-V nitride-based layer. The nitride-based transition layer is disposed between the first III-V nitride-based layer and the second III-V nitride-based layer and in contact with the first III-V nitride-based layer and the second III-V nitride-based layer, in which the nitride-based transition layer is thinner than the first III-V nitride-based layer and the second III-V nitride-based layer. A V/III ratio from the first III-V nitride-based layer to the nitride-based transition layer and then to the second III-V nitride-based layer is strictly decreasing. The nitride-based transistor is disposed over the second III-V nitride-based layer.

By the above configuration, the first III-V nitride-based layer, the nitride-based transition layer, and the III-V nitride-based layer can be formed in the same chamber, such that defects possibly caused during interfaces can be suppressed, thereby improving interface quality among these layers.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1 is a vertical view of an epitaxy base according to some embodiments of the present disclosure;

FIG. 2 is a vertical view of a semiconductor device according to some embodiments of the present disclosure;

FIG. 3 is a vertical view of an epitaxy base according to some embodiments of the present disclosure; and

FIG. 4 is a vertical view of a semiconductor device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

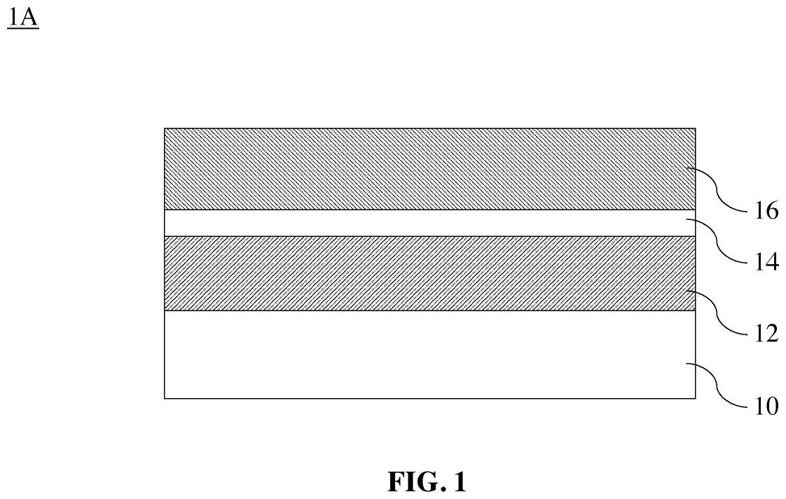

FIG. 1 is a vertical view of an epitaxy base 1A according to some embodiments of the present disclosure. The epitaxy base 1A can serve as a base for semiconductor devices. For example, at least one transistor can be formed from the epitaxy base 1A, in which at least one epitaxy layer may serve as a channel. The epitaxy base 1A includes a substrate 10, a III-V nitride-based layer 12, a nitride-based transition layer 14, and a III-V nitride-based layer 16.

The substrate 10 may be a semiconductor substrate. The exemplary materials of the substrate 10 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 10 can include, for example, but is not limited to, group III elements, group IV elements, group V elements, or combinations thereof (e.g., III-V compounds). In other embodiments, the substrate 10 can include, for example but is not limited to, one or more other features, such as a doped region, a buried layer, an epitaxial (epi) layer, or combinations thereof.

The III-V nitride-based layer 12 is disposed over the substrate 10. The exemplary materials of the III-V nitride-based layer 12 can include, for example but are not limited to, nitrides or group III-V compounds, such as GaN, AlN, InN, InxAlyGa_{(1-x-y})N where x+y≤1, AlyGa_{(1-y})N where y≤1.

The nitride-based transition layer 14 is disposed over the III-V nitride-based layer 12. The nitride-based transition layer 14 can make contact with the III-V nitride-based layer 12. The exemplary materials of the nitride-based transition layer 14 can include, for example but are not limited to, nitrides or group III-V compounds, such as GaN, AlN, InN, InxAlyGa_{(1-x-y})N where x+y≤1, AlyGa_{(1-y})N where y≤1.

The III-V nitride-based layer 16 is disposed over the III-V nitride-based layer 12 and the nitride-based transition layer 14. The III-V nitride-based layer 16 can make contact with the nitride-based transition layer 14. The exemplary materials of the III-V nitride-based layer 16 can include, for example but are not limited to, nitrides or group III-V compounds, such as GaN, AlN, InN, Inx AlyGa_{(1-x-y})N where x+y≤1, AlyGa_{(1-y})N where y≤1.

The nitride-based transition layer 14 can directly connect the III-V nitride-based layer 12 to the III-V nitride-based layer 16. The nitride-based transition layer 14 can provide transition of V/III ratio between the III-V nitride-based layer 12 and the III-V nitride-based layer 16. More specifically, the III-V nitride-based layer 12 is formed by applying a first V/III ratio in a first range; the III-V nitride-based layer 16 is formed by applying a second V/III ratio in a second range, in which the first range and the second range are mutually exclusive; and the nitride-based transition layer 14 is formed by applying a third V/III ratio in a third range between the first range and second range.

The reason for inserting the nitride-based transition layer 14 is for a demand of forming a III-V nitride-based structure with different V/III ratios therein. Once formation of an epitaxy layer over a wafer is terminated and then the wafer is brought into another chamber, defects will be created at a top surface of the epitaxy layer. That is, for a III-V nitride-based structure with different V/III ratios therein, two or more discontinuous manufacturing stages will damage performance of formation.

In some embodiments, the first, second, and third ranges collectively construct a continuous range from 8000 to 200. In some embodiments, an average of the first range is greater than an average of the second range. Variety from the first range to the third range and then to the second range is continuous. As such, the III-V nitride-based layer 12, the nitride-based transition layer 14, and the III-V nitride-based layer 16 can be formed in the same chamber and no need to transfer the base from the chamber until the formation of the III-V nitride-based layer 16 is completed. The nitride-based transition layer 14 can provide transition of middle range of the V/III ratio in 8000 to 200. In some embodiments, the V/III ratio from the III-V nitride-based layer 12 to the nitride-based transition layer 14 and then to the III-V nitride-based layer 16 is strictly decreasing. In some embodiments, the V/III ratio decreasing rate of the nitride-based transition layer 14 is greater than those of the III-V nitride-based layers 12 and 16. In some embodiments, the V/III ratio gradient of the nitride-based transition layer 14 is greater than those of the III-V nitride-based layers 12 and 16.

Since the III-V nitride-based layer 12, the nitride-based transition layer 14, and the III-V nitride-based layer 16 can be formed in the same chamber, defect possibly caused during interfaces can be suppressed. The nitride-based transition layer 14 can form an entirely flat interface with a top surface of the III-V nitride-based layer 12 and form an entirely flat interface with a bottom surface of the III-V nitride-based layer 16. As a V/III ratio transition layer, the nitride-based transition layer 14 is thinner than the III-V nitride-based layers 12 and 16.

With respect to formation of the nitride-based transition layer 14, different optional approaches can be applied thereto. For example, gallium precursor and ammonia keep flowing into a reactor/chamber during transition; aluminum precursor and ammonia keep flowing into a reactor/chamber during transition; or indium precursor and ammonia keep flowing into a reactor/chamber during transition. Since the nitride-based transition layer 14 is configured to accommodate transition, the nitride-based transition layer 14 can have a group III element different than elements contained in the III-V nitride-based layers 12 and 16. Due to different V/III ratios, the III-V nitride-based layer 12 and the III-V nitride-based layer 16 can include the same element but different III-V compositions, for example, AlGaN but different Al concentrations. In some embodiments, the III-V nitride-based layers 12 and 16 may include the same III-V composition.

Although the present embodiment states the V/III ratio decreases from 8000 to 200, it is available that the V/III ratio increases from 200 to 8000 and an average of the first range is less than an average of the second range.

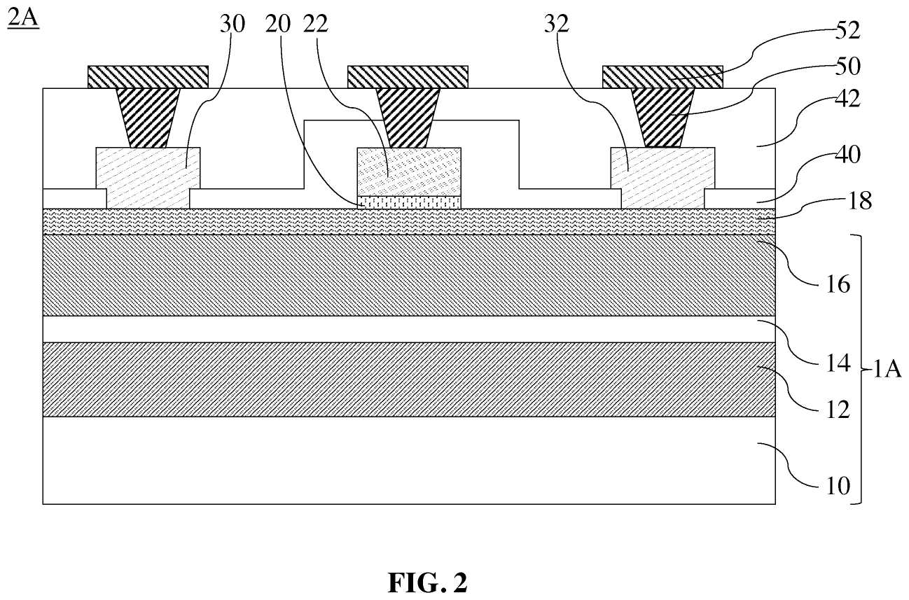

The epitaxy base 1A can be applied to semiconductor devices. FIG. 2 is a vertical view of a semiconductor device 2A according to some embodiments of the present disclosure. The semiconductor device 2A includes an epitaxy base 1A as afore-described. The semiconductor device 2A further includes a III-V nitride-based layer 18, a doped nitride-based semiconductor layer 20, a gate electrode 22, electrodes 30 and 32, passivation layers 40 and 42, contact vias 50, and a patterned conductive layer 52.

The epitaxy base 1A includes a substrate 10, a III-V nitride-based layer 12, a nitride-based transition layer 14, and a III-V nitride-based layer 16, as afore-described. The III-V nitride-based layer 16 can serve as a channel layer.

The III-V nitride-based layer 18 is disposed on/over/above the III-V nitride-based layer 16. The III-V nitride-based layer 18 makes contact with the III-V nitride-based layer 16. The exemplary materials of the III-V nitride-based layer 18 can include, for example but are not limited to, nitrides or group III-V compounds, such as GaN, AlN, InN, InxAlyGa_{(1-x-y)}N where x+y≤1, AlyGa_{(1-y)}N where y≤1.

The exemplary materials of the III-V nitride-based layers 16 and 18 are selected such that the III-V nitride-based layer 18 has a bandgap (i.e., forbidden band width) greater/higher than a bandgap of the III-V nitride-based layer 16, which causes electron affinities thereof different from each other and forms a heterojunction therebetween. As such, the III-V nitride-based layers 16 and 18 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 2A is available to include at least one GaN-based high-electron-mobility transistor (HEMT).

A nitride-based transistor can be disposed over the III-V nitride-based layers 16 and 18. The nitride-based transistor can be constituted by the doped nitride-based semiconductor layer 20, the gate electrode 22, and the electrodes 30 and 32.

The doped nitride-based semiconductor layer 20 and the gate electrode 22 are stacked on the III-V nitride-based layer 18. The doped nitride-based semiconductor layer 20 is between the III-V nitride-based layer 18 and the gate electrode 22.

The semiconductor device 2A can be designed as being an enhancement mode device, which is in a normally-off state when the gate electrode 22 is at approximately zero bias. Specifically, the doped nitride-based semiconductor layer 20 creates a p-n junction with the III-V nitride-based layer 16 to deplete the 2DEG region, such that a zone of the 2DEG region corresponding to a position below the gate electrode 22 has different characteristics (e.g., different electron concentrations) than the rest of the 2DEG region and thus is blocked. Due to such mechanism, the semiconductor device 2A has a normally-off characteristic. In other words, when no voltage is applied to the gate electrode 22 or a voltage applied to the gate electrode 22 is less than a threshold voltage (i.e., a minimum voltage required to form an inversion layer below the gate electrode 22), the zone of the 2DEG region below the gate electrode 22 is kept blocked, and thus no current flows therethrough. Moreover, by providing the doped nitride-based semiconductor layer 20, gate leakage current is reduced and an increase in the threshold voltage during the off-state is achieved.

In some embodiments, the doped nitride-based semiconductor layer 20 can be omitted, such that the semiconductor device 2A is a depletion-mode device, which means the semiconductor device 2A in a normally-on state at zero gate-source voltage.

The exemplary materials of the doped nitride-based semiconductor layer 20 can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Mg, Zn, Cd. In some embodiments, the III-V nitride-based layer 16 includes undoped GaN and the III-V nitride-based layer 18 includes AlGaN, and the doped nitride-based semiconductor layer 20 is a p-type GaN layer which can bend the underlying band structure upwards and deplete the corresponding zone of the 2DEG region, so as to place the semiconductor device 2A into an off-state condition.

In some embodiments, the gate electrode 22 may include metals or metal compounds. The exemplary materials of the metals or metal compounds can include, for example but are not limited to, W, Au, Pd, Ti, Ta, Co, Ni, Pt, Mo, TiN, TaN, metal alloys thereof, or other metallic compounds. In some embodiments, the exemplary materials of the gate electrode 22 may include, for example but are not limited to, nitrides, oxides, silicides, doped semiconductors, or combinations thereof. In some embodiments, the optional dielectric layer can be formed by a single layer or more layers of dielectric materials. The exemplary dielectric materials can include, for example but are not limited to, one or more oxide layers, a SiOx layer, a SiNx layer, a high-k dielectric material (e.g., HfO₂, Al₂O₃, TiO₂, HfZrO, Ta₂O₃, HfSiO₄, ZrO₂, ZrSiO₂, etc), or combinations thereof.

The passivation layer 40 is disposed over the III-V nitride-based layer 18. The passivation layer 40 covers the gate structure for a protection purpose. The exemplary materials of the passivation layer 40 can include, for example but are not limited to, SiNx, SiOx, SiON, SiC, SiBN, SiCBN, oxides, nitrides, or combinations thereof. In some embodiments, the passivation layer 40 is a multi-layered structure, such as a composite dielectric layer of Al₂O₃/SiN, Al₂O₃/SiO₂, AlN/SiN, AlN/SiO₂, or combinations thereof.

The electrodes 30 and 32 are disposed on the III-V nitride-based layer 18. The electrodes 30 and 32 are located at two opposite sides of the gate electrode 22 (i.e., the gate electrode 22 is located between the electrodes 30 and 32). The gate electrode 22 and the electrodes 30 and 32 can collectively act as a GaN-based HEMT with the 2DEG region.

The electrodes 30 and 32 have bottom portions penetrating the passivation layer 40 to form interfaces with the III-V nitride-based layer 18. The electrodes 30 and 32 have top portions wider than the bottom portions thereof. The top portions of the electrodes 30 and 32 extend over portions of the passivation layer 40.

In some embodiments, each of the electrodes 30 and 32 includes one or more conformal conductive layers. In some embodiments, the electrodes 30 and 32 can include, for example but are not limited to, metals, alloys, doped semiconductor materials (such as doped crystalline silicon), other conductor materials, or combinations thereof. The exemplary materials of the electrodes 30 and 32 can include, for example but are not limited to, Ti, AlSi, TiN, or combinations thereof. In some embodiments, each of the electrodes 30 and 32 forms ohmic contact with the III-V nitride-based layer 18. The ohmic contact can be achieved by applying Ti, Al, or other suitable materials for the electrodes 30 and 32.

The passivation layer 42 is disposed above the passivation layer 40 and the electrodes 30 and 32. The passivation layer 42 covers the GaN-based HEMT. The passivation layer 42 covers the electrodes 30 and 32. The passivation layer 42 may have a flat topmost surface, which is able to act as a flat base for carrying layers formed in a step subsequent to the formation thereof. The exemplary materials of the passivation layer 42 can include, for example but are not limited to, SiNx, SiOx, SiON, SiC, SiBN, SiCBN, oxides, nitrides, or combinations thereof. In some embodiments, the passivation layer 42 is a multi-layered structure, such as a composite dielectric layer of Al₂O₃/SiN, Al₂O₃/SiO₂, AlN/SiN, AlN/SiO₂, or combinations thereof.

The contact vias 50 penetrate the passivation layer 42 to connect to the gate electrode 22 and the electrodes 30 and 32. The contact vias 50 form interfaces with the gate electrode 22 and the electrodes 30 and 32. The exemplary materials of the contact vias 50 can include, for example but are not limited to, Cu, Al, or combinations thereof.

The patterned conductive layer 52 is disposed on the passivation layer 42. The patterned conductive layer 52 has a plurality of metal lines over the gate electrode 22 and the electrodes 30 and 32 for the purpose of implementing interconnects between circuits. The metal lines are in contact with the contact vias 50, respectively, such that gate electrode 22 and the electrodes 30 and 32 can be arranged into a circuit. For example, the GaN-based HEMT can be electrically connected to other component(s) via the metal lines of the patterned conductive layer 52. In other embodiments, the patterned conductive layer 52 may include pads or traces for the same purpose.

To run a method for manufacturing the semiconductor device 2A, receipts for the growth of the III-V nitride-based layer 12, the nitride-based transition layer 14, and the III-V nitride-based layer 16 of the epitaxy base 1A can be turned. In the following descriptions, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

In the growth of the III-V nitride-based layer 12, the nitride-based transition layer 14, and the III-V nitride-based layer 16, the steps of a method include: forming a III-V nitride-based layer 12 by applying a first V/III ratio in a first range; forming a III-V nitride-based layer 16 over the III-V nitride-based layer 12 by applying a second V/III ratio in a second range, in which the first range and the second range are mutually exclusive; and forming a nitride-based transition layer 14 between the III-V nitride-based layers 12 and 16 to connect the III-V nitride-based layer 12 with the III-V nitride-based layer 16, in which the nitride-based transition layer 14 is formed by applying a third V/III ratio in a third range between the first range and second range.

During the growth of the III-V nitride-based layer 12, the nitride-based transition layer 14, and the III-V nitride-based layer 16, the V/III ratio can decrease from 8000 to 200. In some embodiments, the V/III ratio can decrease strictly. Since the growth of the III-V nitride-based layer 12, the nitride-based transition layer 14, and the III-V nitride-based layer 16 is performed in the same reactor/chamber, interfaces among layers can be free from atmosphere damaged.

After the growth of the III-V nitride-based layer 12, the nitride-based transition layer 14, and the III-V nitride-based layer 16, a III-V nitride-based layer 18 can be formed in contact with the III-V nitride-based layer 16 to serve as a barrier layer. Thereafter, a nitride-based transistor is formed over the III-V nitride-based layers 16 and 18.

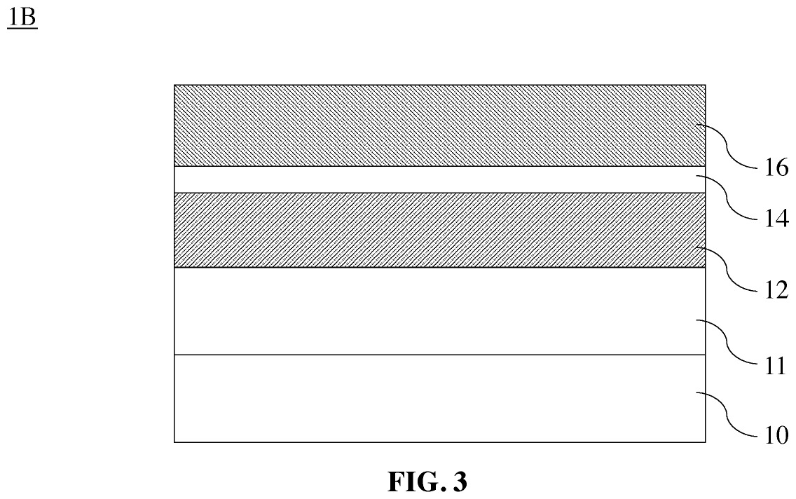

FIG. 3 is a vertical view of an epitaxy base 1B according to some embodiments of the present disclosure. The epitaxy base 1B is similar to the epitaxy base 1B as described and illustrated with reference to FIG. 1, except that the epitaxy base 1B further includes a buffer layer 11.

The buffer layer 11 is disposed between the substrate 10 and the III-V nitride-based layer 12. The buffer layer 11 can be configured to reduce lattice and thermal mismatches between the substrate 10 and the III-V nitride-based layer 12, thereby curing defects due to the mismatches/difference. The buffer layer 11 may include a III-V compound. The III-V compound can include, for example but are not limited to, aluminum, gallium, indium, nitrogen, or combinations thereof. Accordingly, the exemplary materials of the buffer layer 11 can further include, for example but are not limited to, GaN, AlN, AlGaN, InAlGaN, or combinations thereof.

In some embodiments, the epitaxy base 1B may further include a nucleation layer (not shown). The nucleation layer may be formed between the substrate 10 and the buffer layer 11. The nucleation layer can be configured to provide a transition to accommodate a mismatch/difference between the substrate 10 and a III-nitride layer of the buffer layer 11. The exemplary material of the nucleation layer can include, for example but is not limited to AIN or any of its alloys.

The III-V nitride-based layer 12, the nitride-based transition layer 14, and the III-V nitride-based layer 16 are disposed over the buffer layer 11. The III-V nitride-based layer 12, the nitride-based transition layer 14, and the III-V nitride-based layer 16 can have characteristic the same as afore-described at FIG. 1.

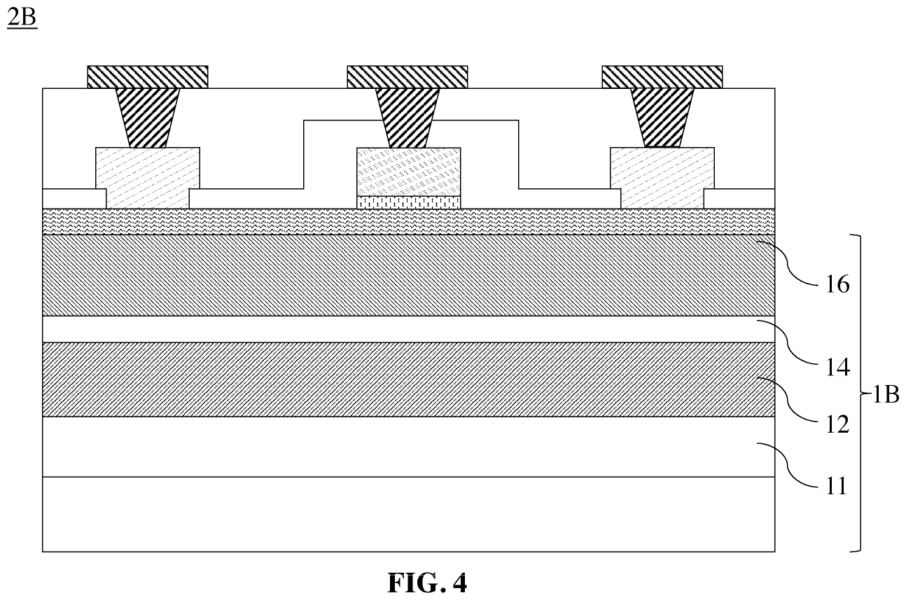

FIG. 4 is a vertical view of a semiconductor device 2B according to some embodiments of the present disclosure. The semiconductor device 2B is similar to the semiconductor device 2A as described and illustrated with reference to FIG. 2, except that an epitaxy base 1B of the semiconductor device 2B further includes a buffer layer 11. The structure of the present disclosure is flexible and thus can be applied to different configurations to comply with different requirements. The III-V nitride-based layer 12, the nitride-based transition layer 14, and the III-V nitride-based layer 16 can collectively serve as a channel layer. The varying V/III ration can enhance the channel characteristic, such as breakdown voltage-related.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor device comprising:
a first III-V nitride-based layer disposed over a substrate by applying a first V/III ratio in a first range;
a second III-V nitride-based layer disposed over the first III-V nitride-based layer by applying a second V/III ratio in a second range, wherein the first range and the second range are mutually exclusive;
a nitride-based transition layer disposed between the first III-V nitride-based layer and the second III-V nitride-based layer to connect the first III-V nitride-based layer with the second III-V nitride-based layer, wherein the nitride-based transition layer is formed by applying a third V/III ratio in a third range between the first range and second range; and
a nitride-based transistor disposed over the second III-V nitride-based layer.

2. The nitride-based semiconductor device of claim 1, further comprising:
a third III-V nitride-based layer disposed between the second III-V nitride-based layer and the nitride-based transistor, wherein the third III-V nitride-based layer has a bandgap higher than a bandgap of the second III-V nitride-based layer.

3. The nitride-based semiconductor device of claim 1, wherein variety from the first range to the third range and then to the second range is continuous.

4. The nitride-based semiconductor device of claim 1, wherein the first, second, and third ranges collectively construct a continuous range from 8000 to 200.

5. The nitride-based semiconductor device of claim 1, wherein an average of the first range is greater than an average of the second range.

6. The nitride-based semiconductor device of claim 1, wherein an average of the first range is less than an average of the second range.

7. The nitride-based semiconductor device of claim 1, wherein the first III-V nitride-based layer and the second III-V nitride-based layer comprise the same III-V composition.

8. The nitride-based semiconductor device of claim 1, wherein the first III-V nitride-based layer and the second III-V nitride-based layer comprise the same element and comprises different III-V compositions.

9. The nitride-based semiconductor device of claim 1, wherein the nitride-based transition layer comprises one of GaN and AlN.

10. (canceled)

11. The nitride-based semiconductor device of claim 1, wherein the nitride-based transition layer comprises indium.

12. The nitride-based semiconductor device of claim 1, wherein the nitride-based transition layer forms an entirely flat interface with the first III-V nitride-based layer.

13. The nitride-based semiconductor device of claim 1, wherein the nitride-based transition layer forms an entirely flat interface with the second III-V nitride-based layer.

14. The nitride-based semiconductor device of claim 1, wherein the nitride-based transition layer is thinner than the first and second III-V nitride-based layers.

15. The nitride-based semiconductor device of claim 1, wherein the nitride-based transition layer has a group III element different than elements contained in the first and second III-V nitride-based layers.

16. A method for manufacturing a nitride-based semiconductor device, comprising:
forming a first III-V nitride-based layer over a substrate by applying a first V/III ratio in a first range;
forming a second III-V nitride-based layer over the first III-V nitride-based layer by applying a second V/III ratio in a second range, wherein the first range and the second range are mutually exclusive;
forming a nitride-based transition layer between the first III-V nitride-based layer and the second III-V nitride-based layer to connect the first III-V nitride-based layer with the second III-V nitride-based layer, wherein the nitride-based transition layer is formed by applying a third V/III ratio in a third range between the first range and second range; and
forming a nitride-based transistor over the second III-V nitride-based layer.

17. The method of claim 16, wherein variety from the first range to the third range and then to the second range is continuous, and the first, second, and third ranges collectively construct a continuous range from 8000 to 200.

18. The method of claim 16, wherein forming the nitride-based transition layer comprises keeping gallium precursor and ammonia flowing into a reactor after forming the first III-V nitride-based layer.

19. The method of claim 16, wherein forming the nitride-based transition layer comprises keeping aluminum precursor and ammonia flowing into a reactor after forming the first III-V nitride-based layer.

20. The method of claim 16, wherein forming the nitride-based transition layer comprises keeping indium precursor and ammonia flowing into a reactor after forming the first III-V nitride-based layer.

21. A nitride-based semiconductor device comprising:
a first III-V nitride-based layer disposed over a substrate;
a second III-V nitride-based layer disposed over the first III-V nitride-based layer;
a nitride-based transition layer disposed between the first III-V nitride-based layer and the second III-V nitride-based layer and in contact with the first III-V nitride-based layer and the second III-V nitride-based layer, wherein the nitride-based transition layer is thinner than the first III-V nitride-based layer and the second III-V nitride-based layer, and a V/III ratio from the first III-V nitride-based layer to the nitride-based transition layer and then to the second III-V nitride-based layer is strictly decreasing; and
a nitride-based transistor disposed over the second III-V nitride-based layer.

22-25. (canceled)
